(19) United States
(12) Patent Application Publication
(10) Pub. No.: US 2025/0071893 A1
(43) Pub. Date: Feb. 27, 2025

(54) CERAMIC SUBSTRATE UNIT AND MANUFACTURING METHOD THEREOF

(71) Applicant: AMOSENSE CO., LTD., Cheonan-si, Chungcheongnam-do (KR)

(72) Inventor: Jihyung LEE, Cheonan-si (KR)

(73) Assignee: AMOSENSE CO., LTD., Cheonan-si, Chungcheongnam-do (KR)

(21) Appl. No.: 18/725,373

(22) PCT Filed: Dec. 15, 2022
(86) PCT No.: PCT/KR2022/020422

§ 371 Date: Jun. 28, 2024

(30) Foreign Application Priority Data
Dec. 31, 2021 (KR) 10-2021-0193798

(51) Int. Cl. H05K 1/03; H05K 1/09; H05K 1/18; H05K 3/07; H05K 3/12

(52) U.S. Cl. CPC H05K 1/0306; H05K 1/09; H05K 1/181; H05K 3/07; H05K 3/1291; H05K 2201/10568; H05K 2201/10674; H05K 2201/2036

(57) ABSTRACT

The present invention relates to a ceramic substrate unit comprising: a ceramic substrate including a ceramic basic material and a circuit pattern formed on the ceramic basic material; an electrode pattern portion included in the circuit pattern on the ceramic substrate and connected to an electrode of a semiconductor chip mounted on the ceramic substrate; and a spacer bonded to the electrode pattern portion of the ceramic substrate by means of a bonding layer, wherein the spacer is made of a metal or alloy having electrical conductivity and thermal conductivity. According to the present invention, a power semiconductor chip can be mounted on a substrate in a form similar to flip-chip bonding, and thus the bonding strength of the bonding surface between a spacer and the substrate is increased to improve the reliability thereof.

### TECHNICAL FIELD

The present disclosure relates to a ceramic substrate unit and a method of manufacturing the same, and more particularly, to a ceramic substrate unit which is applied to a power module and includes a spacer that plays a role as an electric track, and a method of manufacturing the same.

### BACKGROUND ART

A power module is used to supply a high voltage and current for driving a motor for a hybrid vehicle, an electric vehicle, etc.

The power module has a structure in which a power semiconductor chip made of silicon carbide (SiC), gallium nitride (GaN), etc. is mounted on a substrate and a wire made of an Al or Cu material, that is, an electric track for power conversion, is bonded to the power semiconductor chip.

However, in the power module, the wire bonding structure has a danger of a short circuit or a disconnection due to electrical energy having high power and a high current, which is a risk factor for the entire vehicle and becomes a problem.

The contents described in the Background Art are to help the understanding of the background of the disclosure, and may include contents that are not a disclosed conventional technology.

### DISCLOSURE

### Technical Problem

An object of the present disclosure is to provide a ceramic substrate unit, which can omit wire bonding because the ceramic substrate unit includes a spacer that plays a role as an electric track in a substrate so that the spacer plays a role as a power movement track for an electrical signal and power conversion and allows a power semiconductor chip to be mounted on the substrate in a form similar to flip chip bonding, and a method of manufacturing the same.

Furthermore, an object of the present disclosure is to provide a ceramic substrate unit having improved reliability by increasing an adhesive force of a bonding surface between a spacer and a substrate, and a method of manufacturing the same.

### Technical Solution

A ceramic substrate unit according to an embodiment of the present disclosure for achieving the object includes a ceramic substrate including a ceramic base and a circuit pattern formed on the ceramic base, electrode pattern parts included on the circuit pattern of the ceramic substrate and connected to electrodes of a semiconductor chip mounted on the ceramic substrate, and a spacer bonded to the electrode pattern part of the ceramic substrate via a bonding layer. The spacer is made of metal or an alloy having electrical conductivity and thermal conductivity.

The circuit pattern may be made of one of Cu, Al, AlSiC, CuMo, CuW, Cu/CuMo/Cu, Cu/Mo/Cu, Cu/W/Cu alloys or a composite material thereof.

The bonding layer may be made of Ag sintering paste or made of an alloy material including AgCu or AgCuTi.

The thickness of the bonding layer may be in a range of 5 μm to 100 μm.

The spacer may be made of Cu, CuMo, or a CPC material in which Cu, CuMo, and Cu have been sequentially stacked.

Each spacer bonded to the electrode pattern part is connected to each electrode of the semiconductor chip.

The spacers bonded to the electrode pattern parts are bonded to a source electrode, drain electrode, and gate electrode of the semiconductor chip, respectively, through soldering or sintering.

The ceramic substrate unit may further include a plurality of spacers bonded to the remaining parts except the electrode pattern parts in the circuit pattern via the bonding layer.

The plurality of spacers bonded to the remaining parts except the electrode pattern parts in the circuit pattern via the bonding layer have a height greater than the sum of heights of the spacer bonded to the electrode pattern part and the semiconductor chip.

A method of manufacturing a ceramic substrate unit includes a step of preparing a ceramic substrate including a ceramic base, at least one circuit pattern formed on the ceramic base, and electrode pattern parts to be connected to electrodes of a semiconductor chip, respectively, on the circuit pattern, a step of disposing a spacer on the electrode pattern parts of the ceramic substrate via a bonding layer, a step of inserting and pre-heating the ceramic substrate in which the spacer has been disposed into a heating furnace, and a step of main-bonding the spacer to the ceramic substrate by raising a temperature of the heating furnace after the pre-heating step.

In the step of preparing the ceramic substrate, the circuit pattern may be formed by brazing-bonding metal foil made of one of Cu, Al, AlSiC, CuMo, CuW, Cu/CuMo/Cu, Cu/Mo/Cu, Cu/W/Cu alloys or a composite material thereof to the ceramic base and then etching the metal foil.

In the step of preparing the ceramic substrate, the electrode pattern parts may be formed to include a source electrode pattern part, a drain electrode pattern part, and a gate electrode pattern part corresponding to a source electrode, drain electrode, and gate electrode of the semiconductor chip.

In the step of disposing the spacer, the spacer made of a CuMo material or a CPC material in which Cu, CuMo, and Cu have been sequentially stacked may be disposed in the source electrode pattern part and the drain electrode pattern part via a brazing bonding layer.

The brazing bonding layer may be made of an alloy material including AgCu or AgCuTi.

In the step of disposing the spacer, the spacer made of a Cu material is disposed in the gate electrode pattern part via an Ag sintering bonding layer.

The method may further include a step of disposing a plurality of spacers in remaining parts except the electrode pattern parts in the circuit pattern via the bonding layer. The plurality of spacers may be made of a CuMo material or a CPC material in which Cu, CuMo, and Cu have been sequentially stacked.

The step of inserting the ceramic substrate in which the spacer has been disposed into the heating furnace and pre-heating the heating furnace may be performed at 700° C. to 900° C. for 10 minutes to 30 minutes.

The step of main-bonding the spacer to the ceramic substrate by raising the temperature of the heating furnace after the pre-heating step may be performed for 1 hour to 3 hours by making the heating furnace have a reduction atmosphere and raising the temperature of the heating furnace to 860° C. to 950° C.

After the step of main-bonding the spacer to the ceramic substrate by raising the temperature of the heating furnace, a step of processing some spacers bonded to the ceramic substrate in a predetermined shape by etching the some spacers may be performed.

After the step of main-bonding the spacer to the ceramic substrate by raising the temperature of the heating furnace, a step of disposing the spacer made of a Cu material in at least one of the electrode pattern parts via an Ag sintering bonding layer and performing pre-heating and the main bonding may be further performed.

### Advantageous Effects

In the present disclosure, one or more spacers are bonded to both sides or one side of the ceramic substrate through brazing bonding or Ag sintering bonding so that the spacer plays a role for an electrical signal and plays a role as a power movement track for power conversion. Accordingly, the present disclosure has effects in that wire bonding can be omitted, both multiple multi-quantity connections and heat dissipation effect of the semiconductor chip can be secured by applying the present disclosure to a power module, and performance of the power module can be further improved because the present disclosure also contributes to miniaturization.

Furthermore, the present disclosure has an effect in that reliability can be improved by increasing an adhesive force between the spacer and the substrate because the ceramic substrate and the spacer are bonded through brazing bonding and Ag sintering.

### DESCRIPTION OF DRAWINGS

FIG. 1 is a bottom view illustrating a ceramic substrate unit according to a first embodiment of the present disclosure.

FIG. 2 is a plan view illustrating the ceramic substrate unit according to the first embodiment of the present disclosure.

FIG. 3 is a cross-sectional view of a-a in FIG. 1.

FIG. 4 is a cross-sectional view of b-b in FIG. 1.

FIG. 5 is a cross-sectional view of c-c in FIG. 1.

FIG. 6 is a cross-sectional view of d-d in FIG. 1.

FIG. 7 is a diagram illustrating a form in which a semiconductor chip has been attached to the ceramic substrate unit according to the first embodiment of the present disclosure.

FIG. 8 is a cross-sectional view of e-e in FIG. 7.

FIG. 9 is a flowchart illustrating a method of manufacturing a ceramic substrate unit according to a first embodiment of the present disclosure.

FIG. 10 is a construction diagram illustrating the method of manufacturing a ceramic substrate unit according to the first embodiment of the present disclosure.

FIG. 11A is a plan view of a ceramic substrate unit in which spacers have been bonded to a cross section of the ceramic substrate as a second embodiment of the present disclosure.

FIG. 11B is a bottom view of the ceramic substrate unit in which spacers have been bonded to a cross section of the ceramic substrate as the second embodiment of the present disclosure.

FIG. 11C is a front view of the ceramic substrate unit in which spacers have been bonded to a cross section of the ceramic substrate as the second embodiment of the present disclosure.

### MODE FOR INVENTION

Hereinafter, preferred embodiments of the present disclosure are described in detail with reference to the accompanying drawings.

A ceramic substrate unit of the present disclosure is characterized in that one or more spacers are bonded to both sides or one side of a ceramic substrate so that the spacer plays a role for an electrical signal and plays a role as a power movement track for power conversion.

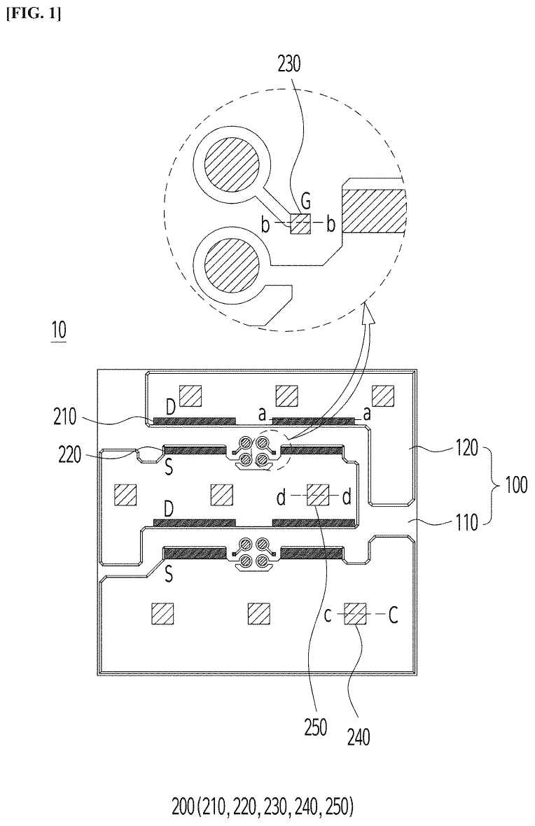

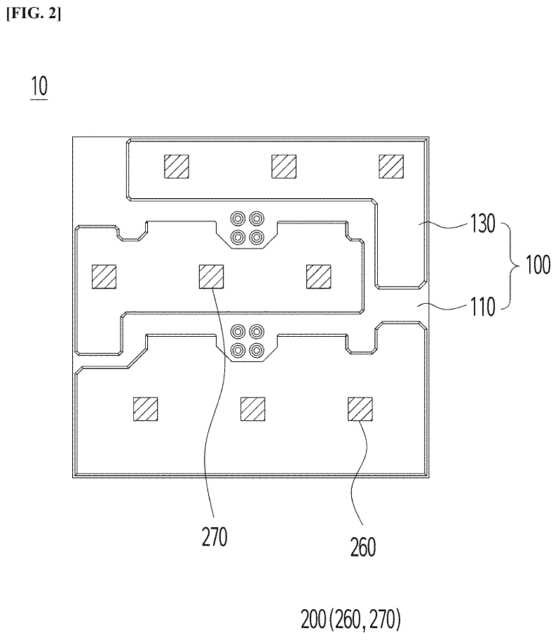

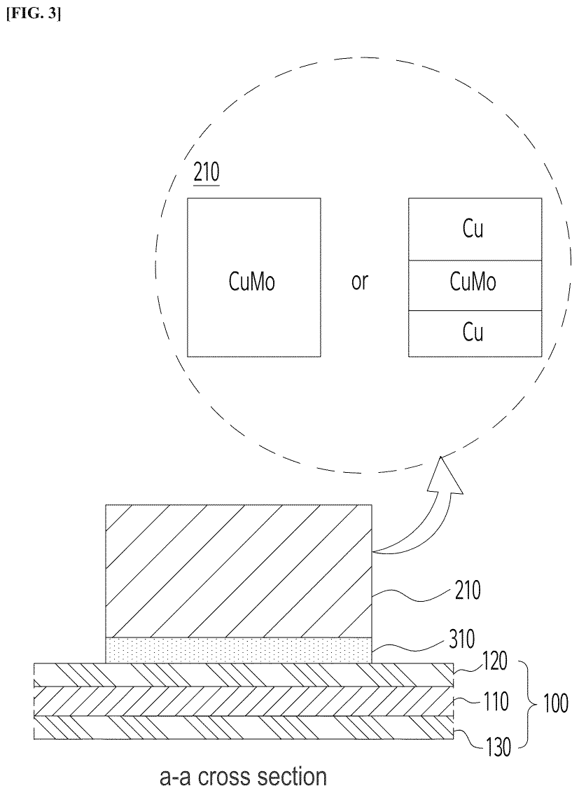

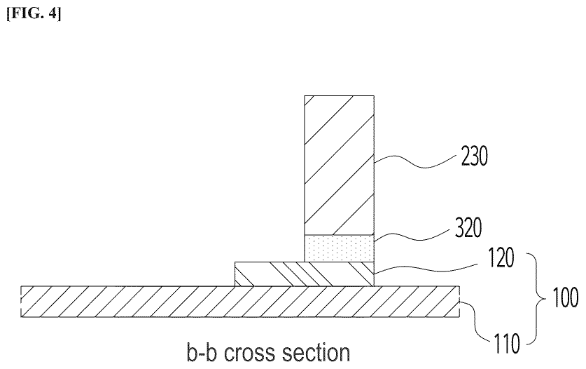

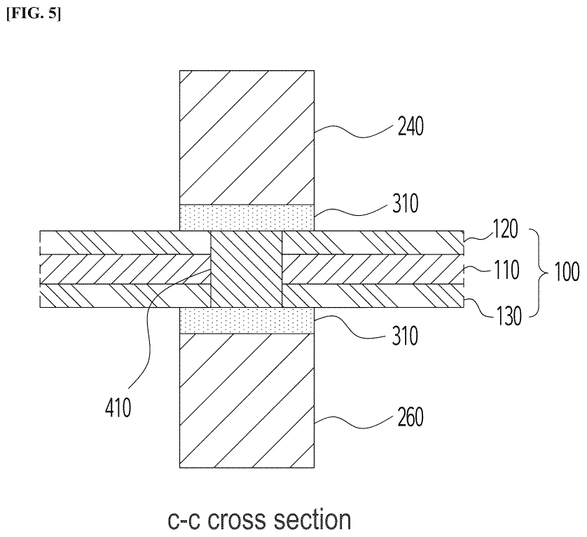

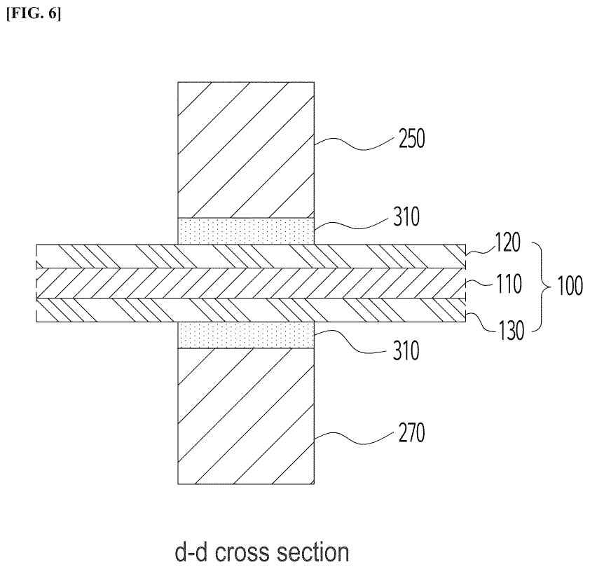

FIG. 1 is a bottom view illustrating a ceramic substrate unit according to a first embodiment of the present disclosure. FIG. 2 is a plan view illustrating the ceramic substrate unit according to the first embodiment of the present disclosure. FIG. 3 is a cross-sectional view of a-a in FIG. 1. FIG. 4 is a cross-sectional view of b-b in FIG. 1. FIG. 5 is a cross-sectional view of c-c in FIG. 1. FIG. 6 is a cross-sectional view of d-d in FIG. 1. For reference, in the cross sections of FIGS. 3 to 6, a relative thickness or length or a relative size has been exaggerated and shown, for convenience and clarity of a description.

As illustrated in FIGS. 1 and 2, a ceramic substrate unit 10 according to the first embodiment of the present disclosure includes a ceramic substrate 100 and a spacer 200 bonded to both sides of the ceramic substrate 100.

The ceramic substrate 100 may be any one of an active metal brazing (AMB) substrate, a direct bonding copper (DBC) substrate, a thick printing copper (TPC) substrate, and a DBA substrate. The AMB substrate or the BDC substrate is most suitable in terms of durability and heat dissipation efficiency.

For example, the ceramic substrate 100 includes a ceramic base 110 and at least one circuit pattern 120, 130 formed on the ceramic base 110. The ceramic base 110 may be any one of alumina (Al₂O₃), AlN, SiN, and Si₃N₄, for example.

The circuit pattern 120, 130 may be formed on both sides of the ceramic base 110. The both sides of the ceramic base 110 may mean an upper surface and lower surface of the ceramic base 110. The circuit pattern 120, 130 may be made of one of Cu, Al, AlSiC, CuMo, CuW, Cu/CuMo/Cu, Cu/Mo/Cu, Cu/W/Cu alloys or a composite material thereof. The circuit pattern 120, 130 may be formed by brazing-bonding metal foil made of one of Cu, Al, AlSiC, CuMo, CuW, Cu/CuMo/Cu, Cu/Mo/Cu, Cu/W/Cu alloys or a composite material thereof to the ceramic base 110 and then etching the metal foil. The thickness of the ceramic base 110 may be 0.32 t, and the thickness of each circuit pattern 120, 130 may be 0.3 t. If the circuit pattern 120, 130 is formed on both sides of the ceramic base 110, it is preferred that the thicknesses of the circuit patterns 120, 130 are the same so that the circuit patterns are not deformed upon brazing.

The circuit pattern 120, 130 may be formed to include an electrode pattern part to be connected to an electrode of a semiconductor chip 500 that is mounted on the ceramic substrate 100.

Specifically, the circuit pattern 120, 130 may be formed to include a source electrode pattern part S, a drain electrode pattern part D, and a gate electrode pattern part G. A source terminal of the semiconductor chip is connected to the source electrode pattern part S of the circuit pattern 120, 130. A drain terminal of the semiconductor chip is connected to the drain electrode pattern part D of the circuit pattern 120, 130. A gate terminal of the semiconductor chip is connected to the gate electrode pattern part G of the circuit pattern 120, 130. The semiconductor chip may be a semiconductor chip that functions as a high power switch and a high speed switch, and may be any one of a Si chip, a SiC chip, or a gallium nitride (GaN) chip, for example. The source terminal and drain terminal of the semiconductor chip are terminals that are responsible for the input and output of a high current, and the gate terminal thereof is a terminal that turns on and off the semiconductor chip by using a low voltage.

The spacer 200 is bonded to the electrode pattern part of the circuit pattern on the ceramic substrate 100 for each location in a plural number, and plays a role for an electrical signal or plays a role as a power movement track for power conversion. The spacer 200 is made of metal or an alloy material having electrical conductivity and thermal conductivity so that the spacer plays a role for an electrical signal or plays a role as a power movement track for power conversion.

The spacer 200 may be made of one of Cu, CuMo, and CPC materials, which have a low coefficient of thermal expansion and excellent electrical conductivity and thermal conductivity. The CPC material has a form in which Cu, CuMo, and Cu have been sequentially stacked. For example, the spacers 210 and 220 made of the CuMo material or the CPC material may be bonded to the source electrode pattern part S and the drain electrode pattern part D. The spacer 230 made of a Cu material may be bonded to the gate electrode pattern part G. The spacers 210 and 220 that are bonded to the source electrode pattern part S and the drain electrode pattern part D may be fabricated by machine processing because each spacer has a predetermined size. The spacer 230 that is bonded to the gate electrode pattern part G may be formed to have a desired size and shape by bonding the spacer having a predetermined size, which is fabricated by machine processing, to the gate electrode pattern part and then etching the spacer because the size of the spacer needs to be small. For example, the spacer 230 that is bonded to the gate electrode pattern part G may be formed in a quadrangle block shape or a square pyramid shape a cross-sectional area of which becomes smaller toward an upper part thereof.

Furthermore, the spacer 200 may be bonded to both sides of the ceramic substrate 100 for each location depending on its function. For example, some spacer 240, among all of the spacers 200, may be bonded to the circuit pattern 120, 130 except the electrode pattern parts, and may perform the function of a heat dissipation electrode that isolates the ceramic substrate and another ceramic substrate that is disposed over or under the ceramic substrate and that electrically connects the circuit pattern 120 of the ceramic substrate 100 and a circuit pattern of another ceramic substrate.

Furthermore, some spacer 250 may be bonded to the circuit pattern 120, 130 except the electrode pattern parts, and may perform a function for increasing heat dissipation efficiency by isolating the ceramic substrate 100 and another ceramic substrate (not illustrated) that is disposed over or under the ceramic substrate. For example, if the circuit pattern 120 of the ceramic substrate 100 on which a semiconductor chip is mounted is connected to a circuit pattern of another ceramic substrate that is disposed under the ceramic substrate 100 by the spacer 250 having thermal conductivity, heat that is generated from the semiconductor chip can be rapidly discharged, and a function for stably protecting the semiconductor chip that is disposed between the ceramic substrate 100 and the underlying another ceramic substrate can also be performed. The spacer 240, 250 that is bonded to the ceramic substrate 100 and that isolates the ceramic substrate 100 and another ceramic substrate 100 disposed over or under the ceramic substrate is preferably made of the CuMo material or the CPC material, and may be bonded to the ceramic substrate 100 after the spacer is fabricated by machine processing because the spacer has a predetermined size.

Specifically, some spacers 210, 220, and 230 are bonded to the drain electrode pattern part D, source electrode pattern part S, and gate electrode pattern part G of the ceramic substrate 100, respectively, so that the semiconductor chip is mounted on the ceramic substrate 100 in a form similar to a flip chip. When the semiconductor chip is bonded to the ceramic substrate 100 by using the spacers 210, 220, and 230, an electrical loss and load attributable to resistance on a power transfer path can be improved because a power transfer path is reduced. Furthermore, the spacers 210, 220, and 230 may play a role for an electrical signal and play a role as a power movement track for power conversion instead of conventional wire bonding. If wire bonding is omitted, there is an effect in that heat dissipation performance is improved because an inductance value can be reduced to the maximum.

Furthermore, some spacers 240 and 250 are bonded to the circuit pattern 120 except the electrode pattern parts of the ceramic substrate 100, and can improve electrical characteristics by preventing an electrical loss and short because the spacers can electrically connect the circuit pattern 120 of the ceramic substrate 100 and a circuit pattern of another ceramic substrate. Furthermore, the spacer 240, 250 that electrically connects the circuit pattern 120 of the ceramic substrate 100 and a circuit pattern of another ceramic substrate can improve an electrical loss and load attributable to resistance on a power transfer path because a power transfer path is reduced.

Referring to FIG. 1, the spacers 210, 220, and 230 are bonded to the drain electrode pattern part D, the source electrode pattern part S, and the gate electrode pattern part G, respectively, on the lower surface of the ceramic substrate 100. Multiple spacers 240 and 250 are bonded to the remaining parts of the circuit pattern 120 except the electrode pattern parts at predetermined intervals in order to increase isolation from another ceramic substrate 100, a power movement, and heat dissipation efficiency.

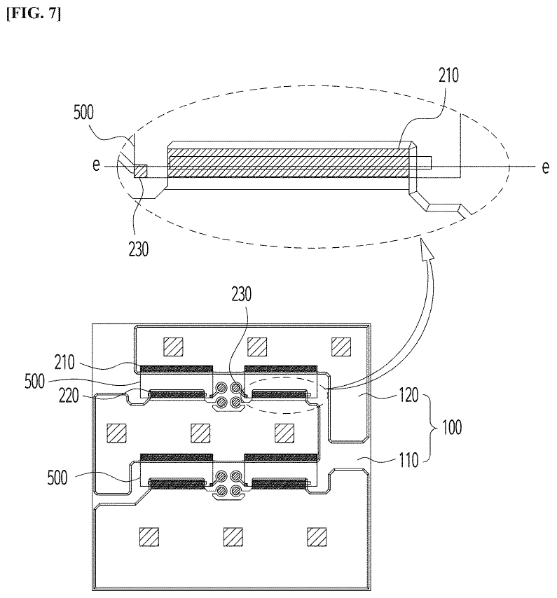

The spacers 210, 220, and 230 may be bonded to the electrode pattern parts to be connected to electrodes of the semiconductor chip (reference numeral 500 in FIG. 7) in the circuit pattern 120. The spacers 210, 220, and 230 that are bonded to the electrode pattern parts are connected to the electrodes of the semiconductor chip, respectively, and may each play a role as a high current power movement track for power conversion or play a role for an electrical signal.

Referring to FIG. 2, multiple spacers 260 and 270 may be bonded to the upper surface of the ceramic substrate 100 at predetermined intervals in order to isolate the ceramic substrate from another ceramic substrate 100 at the part of the circuit pattern 130 and to increase heat dissipation efficiency.

As illustrated in FIG. 3, the spacer 210 that is bonded to the drain electrode pattern part D may be made of the CuMo material or may be made of the CPC material in which Cu, CuMo, and Cu have been sequentially stacked.

In an embodiment, the spacer 200 that is bonded to the ceramic substrate 100 is bonded to the circuit pattern 120 of the ceramic substrate 100 via a bonding layer 310, 320. The bonding layer 300 may be a brazing bonding layer 310 or an Ag sintering bonding layer 320. The spacer 210 is bonded to the drain electrode pattern part D illustrated in FIG. 3 via the brazing bonding layer 310.

The brazing bonding layer 310 may be made of an alloy material including AgCu or AgCuTi. The thickness of the brazing bonding layer 310 may be in the range of 5 μm to 100 μm. The thickness of the brazing bonding layer 310 is small to the extent that the thickness does not affect the height of the spacer 210, and bonding strength thereof is great.

Furthermore, the spacer 220 that is bonded to the source electrode pattern part S of FIG. 1 may be made of the CuMo material or the CPC material in which Cu, CuMo, and Cu have been sequentially stacked. Furthermore, the spacer 220 is bonded to the source electrode pattern part S via the brazing bonding layer 310.

As illustrated in FIG. 4, the spacer 230 that is bonded to the gate electrode part G may be made of the Cu material. Furthermore, the spacer 230 may be bonded to the gate electrode part G via the Ag sintering bonding layer 320. The Ag sintering bonding layer 320 includes Ag nano particle powder, and has high bonding density and high thermal conductivity.

The Ag sintering bonding layer 320 having high bonding density is applied to the gate electrode part G that is difficult to be bonded because the gate electrode part has a small size in order to increase bonding strength between the circuit pattern 120 and the spacer 200. Furthermore, Cu which can be relatively easily processed is applied to the spacer 230 of the gate electrode part G in order to increase the precision of the size so that the spacer plays a reliable role for an electrical signal. Particularly, the Ag sintering bonding layer 320 improves efficiency by reducing an electrical loss of an electrical signal connection part.

The spacers 240, 250, 260, and 270 illustrated in FIGS. 1 and 2 are bonded to the remaining parts except the electrode pattern parts in the circuit pattern 120, 130. The spacers 240, 250, 260, and 270 that are bonded to the remaining parts except the electrode pattern parts in the circuit pattern 120, 130 are disposed at predetermined intervals in a plural number, and may each perform a heat dissipation function between a substrate and a substrate or play a role for an electrical signal.

As illustrated in FIG. 5, the spacer 240, 260 is bonded to the circuit pattern 120, 130, and may perform a function for electrifying the upper circuit pattern 120 and the lower electrode pattern 130 by connecting the upper circuit pattern 120 and the lower electrode pattern 130 in the drawing and for conducting a high current and distributing a high current. To this end, a via hole 410 is formed in the ceramic substrate 100. The upper circuit pattern 120, the lower electrode pattern 130, and the spacer 200 may be electrically connected through the via hole 410. The via hole 410 may be filled with a conductive material, and may be filled with an Ag alloy, for example.

The spacer 240, 260 may be made of the CuMo material or may be made of the CPC material in which Cu, CuMo, and Cu have been sequentially stacked. The spacer 240, 260 may be bonded to the circuit pattern 120, 130 of the ceramic substrate 100 via the brazing bonding layer 310 that is made of an alloy material including AgCu or AgCuTi.

As illustrated in FIG. 6, the spacer 250, 270 is bonded to the circuit pattern 120, 130, and may perform a function of a heat dissipation electrode that isolates the ceramic substrate 100 and another ceramic substrate (not illustrated) that is disposed over or under the ceramic substrate in the drawing and that electrically connects the circuit pattern 120, 130 of the ceramic substrate 100 and a circuit pattern of another ceramic substrate.

The spacer 250, 270 may be made of the CuMo material or may be made of the CPC material in which Cu, CuMo, and Cu have been sequentially stacked. The spacer 250, 270 may be bonded to the circuit pattern 120, 130 of the ceramic substrate 100 via the brazing bonding layer 310 that is made of an alloy material including AgCu or AgCuTi.

The spacers 240, 250, 260, and 270 illustrated in FIGS. 5 and 6 are bonded to the remaining parts except the electrode pattern parts in the circuit pattern 120, 130 via the brazing bonding layer 310, and each perform heat dissipation and support functions between two substrates. Accordingly, each spacer has a height greater than the sum of the heights of the spacers 210, 220, and 230 bonded to the electrode pattern parts and the semiconductor chip 500.

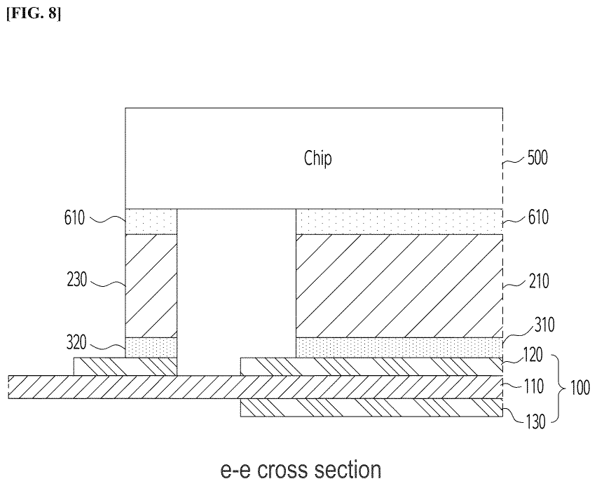

FIG. 7 is a diagram illustrating a form in which the semiconductor chip has been attached to the ceramic substrate unit according to the first embodiment of the present disclosure. FIG. 8 is a cross-sectional view of e-e in FIG. 7. In the cross section of FIG. 8, a relative thickness or length or a relative size has been exaggerated and shown, for convenience and clarity of a description.

As illustrated in FIGS. 7 and 8, the drain electrode, source electrode, and gate electrode of the semiconductor chip 500 may be bonded to the drain electrode pattern part D, source electrode pattern part S, and gate electrode pattern part G of the ceramic substrate 100, respectively. A bonding layer 610 that bonds the drain electrode, source electrode, and gate electrode of the semiconductor chip 500 to the drain electrode pattern part D, source electrode pattern part S, and gate electrode pattern part G of the ceramic substrate 100, respectively, may be a solder or Ag sintering paste. SnAg, SnAgCu, etc., which have high bonding strength and excellent high-temperature reliability, may be used for soldering bonding through the solder. Ag sintering paste including Ag nano powder having high bonding density and high thermal conductivity may be used for Ag sintering using the Ag sintering paste.

A structure in which the semiconductor chip 500 is bonded to the ceramic substrate 100 through the spacers 210, 220, and 230 bonded to the ceramic substrate 100 can improve an electrical loss and load because the semiconductor chip 500 is mounted on the ceramic substrate 100 in a form similar to a flip chip and increase operation reliability by enabling the stable mounting of the semiconductor chip 500.

In an embodiment, one or more semiconductor chips 500 may be mounted on the ceramic substrate 100. The spacer 200 may be bonded to the ceramic substrate 100 by considering the number and locations of the drain electrode, source electrode, and gate electrode of the semiconductor chip 500.

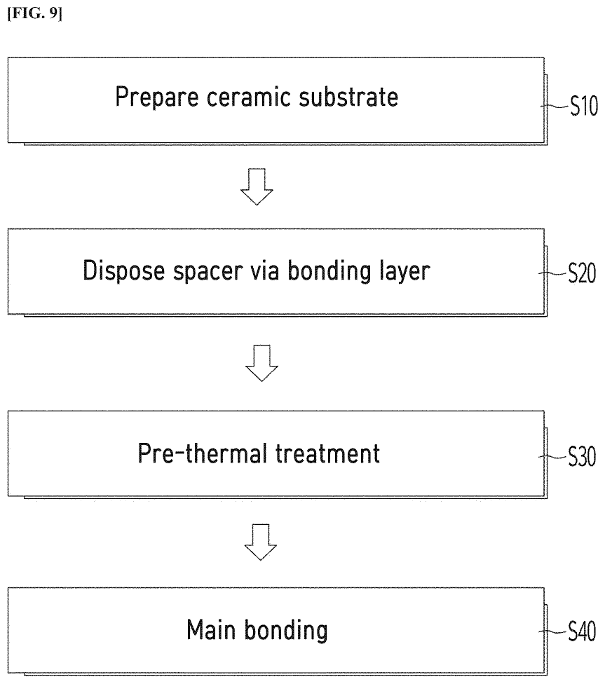

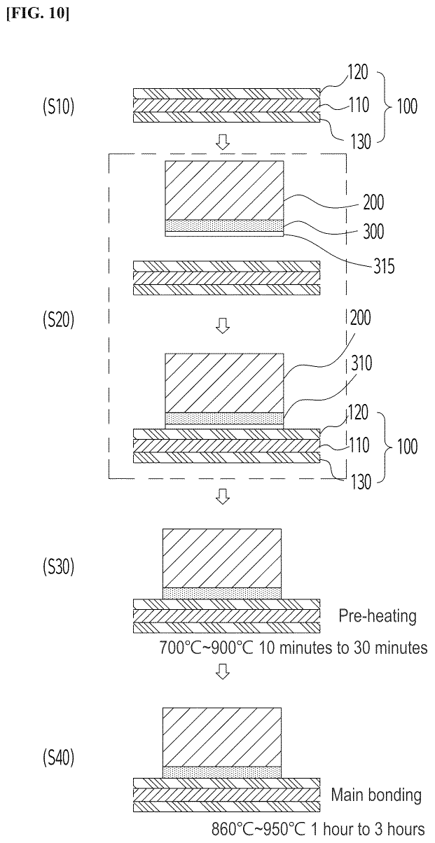

FIG. 9 is a flowchart illustrating a method of manufacturing a ceramic substrate unit according to a first embodiment of the present disclosure. FIG. 10 is a construction diagram illustrating the method of manufacturing a ceramic substrate unit according to the first embodiment of the present disclosure.

As illustrated in FIGS. 9 and 10, the method of manufacturing a ceramic substrate unit according to the first embodiment of the present disclosure includes step S10 of preparing the ceramic substrate 100 including the ceramic base 110, at least one circuit pattern 120, 130 formed on the ceramic base 110, and electrode pattern parts to be connected to electrodes of the semiconductor chip 500, respectively, on the circuit pattern 120, 130, step S20 of disposing the spacers 200 on the electrode pattern parts of the ceramic substrate 100 via the bonding layer 300, step S30 of inserting and pre-heating the ceramic substrate 100 in which the spacers 200 have been disposed into a heating furnace, and step S40 of main-bonding the spacers 200 to the ceramic substrate 100 by raising the temperature of the heating furnace after the pre-heating step.

In step S10 of preparing the ceramic substrate 100, the circuit pattern 120, 130 may be formed by brazing-bonding metal foil made of one of Cu, Al, AlSiC, CuMo, CuW, Cu/CuMo/Cu, Cu/Mo/Cu, Cu/W/Cu alloys or a composite material thereof to the ceramic base 110 and then etching the metal foil.

In step S10 of preparing the ceramic substrate 100, the circuit pattern 120, 130 may be formed to include a source electrode pattern part, a drain electrode pattern part, and a gate electrode pattern part corresponding to the source electrode, drain electrode, and gate electrode of the semiconductor chip 500.

In step S20 of disposing the spacer 200 in the electrode pattern parts of the ceramic substrate 100 via the bonding layer 300, the spacer made of the CuMo material or the CPC material in which Cu, CuMo, and Cu have been sequentially stacked may be disposed in the source electrode pattern part and the drain electrode pattern part via a brazing bonding layer. The brazing bonding layer may be made of an alloy material including AgCu or AgCuTi.

In step S20 of disposing the spacer 200 in the electrode pattern parts of the ceramic substrate 100 via the bonding layer 300, the spacer made of the Cu material may be disposed in the gate electrode pattern part via the Ag sintering bonding layer. The Ag sintering bonding layer includes Ag nano powder. The Ag nano powder may be sintered in the brazing process, and can firmly bond the spacer 200 to the circuit pattern of the ceramic substrate 100.

In step S20 of disposing the spacer 200 in the electrode pattern parts of the ceramic substrate 100 via the bonding layer 300, the brazing bonding layer 310 of the bonding layer 300 may be attached on one side of the spacer 200 through a transcription method and then temporarily attached to the circuit pattern 120 of the ceramic substrate 100 via the adhesive layer 315.

Alternatively, the brazing bonding layer 310 of the bonding layer 300 may be formed by forming the brazing bonding layer on the circuit pattern 120, 130 of the ceramic substrate 100 through sputtering and a plating method and then etching the brazing bonding layer. The spacer 200 may be temporarily attached to the bonding layer 300 formed on the circuit pattern 120, 130 of the ceramic substrate 100 via the adhesive layer 315.

Alternatively, the Ag sintering bonding layer 320 of the bonding layer 300 may be attached to one side of the spacer 200 through a method, such as transcription, application, or coating and then temporarily attached to the circuit pattern 120 of the ceramic substrate 100 via the adhesive layer 315.

Step S30 of inserting and pre-heating the ceramic substrate 100 in which the spacer 200 has been disposed into a heating furnace may be performed at 700° C. to 900° C. for 10 minutes to 30 minutes while passing the ceramic substrate 100 in which the spacer 200 has been disposed through a continuous furnace (heating furnace). The pre-heating step S30 is for removing thermal stress and thermal deformation of the ceramic substrate 100. The pre-heating step S30 is for preventing a crack in or the bending of the ceramic substrate 100 by preventing a sudden thermal shock along with overall crack heating.

In the pre-heating step S30, when a pre-heating temperature is lower than the range, a pre-heating effect is not present. When the pre-heating temperature is higher than the range, it is difficult to remove thermal stress and thermal deformation. In the pre-heating step S30, a preferred pre-heating condition includes about 15 minutes to 20 minutes at 760° C. to 800° C.

Step S40 of main-bonding the spacer 200 to the ceramic substrate 100 by raising the temperature of the heating furnace after the pre-heating step may be performed for 1 hour to 3 hours by making the atmosphere of the heating furnace have a reduction atmosphere and raising the temperature of the heating furnace to 860° C. to 950° C. In order to make the atmosphere of the heating furnace the reduction atmosphere, nitrogen may be injected into the heating furnace.

More preferably, after the ceramic substrate 100 to which the spacer 200 has been temporarily bonded is pre-heated, the spacer 200 is brazing-bonded to the ceramic substrate 100 while the ceramic substrate passes through a continuous furnace (the heating furnace) having a reduction atmosphere. The brazing bonding is performed on the ceramic substrate 100 to which the spacer 200 has been temporarily bonded in the continuous furnace having the reduction atmosphere, in a temperature range of 860° C. to 950° C. for 1 hour to 3 hours. In this case, both brazing bonding and cooling may be performed on the ceramic substrate 100 to which the spacer 200 has been temporarily bonded in a process of the ceramic substrate passing through the continuous furnace.

It is not preferred that in the main-bonding step S40, a main-bonding temperature is lower than the range because bonding strength is low and the main-bonding temperature is higher than the range because a crack, bending, etc. may occur in the ceramic substrate 100. In the main-bonding step S40, a preferred main-bonding condition includes about 1 hour 30 minutes to 2 hours 10 minutes at 900° C. to 950° C.

The spacer 200 that has been temporarily bonded to the circuit pattern 120, 130 of the ceramic substrate 100 via the brazing bonding layer 310 in the main-bonding process is bonded to the ceramic substrate 100 through brazing bonding. The spacer 200 that has been temporarily bonded to the circuit pattern 120, 130 of the ceramic substrate 100 via the Ag sintering bonding layer 320 is bonded through Ag sintering. Alternatively, the adhesive layer 315 that temporarily bonds the spacer 200 to the ceramic substrate 100 becomes volatile and is removed in the brazing bonding process.

Alternatively, after one brazing bonding process of bonding the spacer 200 to the circuit pattern 120, 130 of the ceramic substrate 100 via the brazing bonding layer 310, the spacer 200 may be bonded to the circuit pattern 120, 130 of the ceramic substrate 100 via the Ag sintering bonding layer 320.

For example, after step S40 of main-bonding the spacer to the circuit pattern of the ceramic substrate, a step of disposing one or more spacers 230 on the circuit pattern of the ceramic substrate 100 via the Ag sintering bonding layer (reference numeral 320 in FIG. 4 may be additionally performed. In the step of additionally performing the step of disposing the one or more spacers 230 on the circuit pattern 120 of the ceramic substrate 100 via the Ag sintering bonding layer 320, a second brazing bonding process of disposing the spacer 230 made of the Cu material in the gate electrode pattern part G via the Ag sintering bonding layer 320 and additionally performing a pre-heating and main bonding process may be performed.

If the second brazing bonding process is performed, a void defect that occurs in a bonding surface of the spacer 200 and the ceramic substrate 100 in the first brazing bonding process may be removed. Furthermore, bonding strength between the ceramic substrate 100 and the spacer 230 may be increased by more accurately controlling a bonding temperature of the Ag sintering bonding layer 320.

After the step S40 of main-bonding the spacers 200 to the circuit pattern 120, 130 of the ceramic substrate 100 by raising the temperature of the heating furnace, a step of processing some of the spacers 200 bonded to the ceramic substrate 100 in a predetermined shape by etching some of the spacers may be performed. For example, the spacer (reference numeral 230 in FIG. 4) bonded to the gate electrode pattern part G may be made in a small shape by etching the spacer.

The ceramic substrate unit 10 that is manufactured by the method is bonded to both sides of the ceramic substrate 100 in a plural number for each location, and may play a role for an electrical signal and play a role as a power movement track for power conversion instead of wire bonding.

An example in which the spacer 200 is bonded to both sides of the ceramic substrate 100 for each location has been described, but the spacer may be bonded to only one side of the ceramic substrate 100 for each location.

Furthermore, the spacer 200 may be bonded to one side of the ceramic substrate 100 for each location, and may play a role for an electrical signal only.

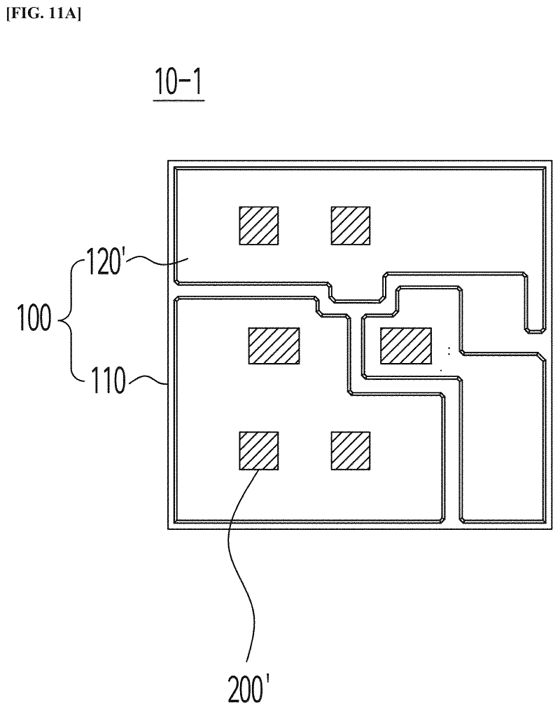

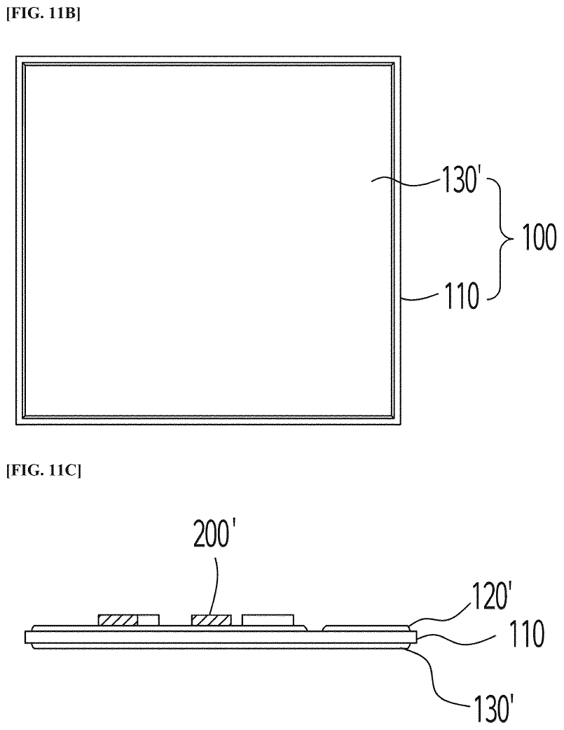

FIG. 11A is a plan view of a ceramic substrate unit in which spacers have been bonded to a cross section of a ceramic substrate as a second embodiment of the present disclosure. FIG. 11B is a bottom view of the ceramic substrate unit in which spacers have been bonded to a cross section of the ceramic substrate as the second embodiment of the present disclosure. FIG. 11C is a front view of the ceramic substrate unit in which spacers have been bonded to a cross section of the ceramic substrate as the second embodiment of the present disclosure.

As illustrated in FIG. 11A to 11C, in a ceramic substrate unit 10-1 of the second embodiment, a plurality of spacers 200′ may be bonded to one side of the ceramic substrate 100 at predetermined intervals. The spacer 200′ may be bonded to a circuit pattern 120′ of the ceramic substrate 100 via the brazing bonding layer or the Ag sintering bonding layer depending on its use. For example, the spacer 200′ may be bonded to one side of the ceramic substrate 100 in a plural number at predetermined intervals, and may perform a function of a heat dissipation electrode that isolates the ceramic substrate 100 from another ceramic substrate that is disposed over and under the ceramic substrate 100 and electrically connects the circuit pattern 120′ of the ceramic substrate 100 and a circuit pattern of another ceramic substrate.

In the first embodiment, an example in which the spacers are bonded to the drain electrode pattern part, source electrode pattern part, and gate electrode pattern part of the ceramic substrate 100, respectively, and the semiconductor chip may be mounted has been described. In the second embodiment, an example in which the spacers 200′ are bonded to only one side of the ceramic substrate 100 and each perform a heat dissipation function or play a role for an electrical signal has been described. However, in order to design a structure not having wire bonding, the spacer having various forms, such as a quadrangle block shape and a cylindrical shape, and various size may be bonded to the ceramic substrate for each location.

The present disclosure can improve reliability by increasing an adhesive force of a bonding surface because the spacer is bonded to one side or both sides of the ceramic substrate through brazing bonding or Ag sintering, can have an excellent heat dissipation characteristic because the spacer is made of a material having excellent thermal conductivity, and can stably play a role for an electrical signal and play a role as a power movement track for power conversion because the spacer has electrical conductivity. Furthermore, the present disclosure can remove an electrical risk factor in wire bonding because wire bonding is omitted, can simultaneously convert a rating voltage and current, and can improve reliability and efficiency of a part that is used in high power, particularly.

Furthermore, the ceramic substrate unit of the present disclosure can secure both multiple multi-quantity connections and a heat dissipation effect of a semiconductor chip by being applied to a power module, and can further improve performance of the power module because the ceramic substrate unit also contributes to miniaturization.

The ceramic substrate of the present disclosure may be applied to various module parts which are used in high power, in addition to a power module.

The above description is merely a description of the technical spirit of the present disclosure, and those skilled in the art may change and modify the present disclosure in various ways without departing from the essential characteristic of the present disclosure. Accordingly, the embodiments described in the present disclosure should not be construed as limiting the technical spirit of the present disclosure, but should be construed as describing the technical spirit of the present disclosure. The technical spirit of the present disclosure is not restricted by the embodiments. The range of protection of the present disclosure should be construed based on the following claims, and all of technical spirits within an equivalent range of the present disclosure should be construed as being included in the scope of rights of the present disclosure.

1. A ceramic substrate unit comprising:
a ceramic substrate comprising a ceramic base and a circuit pattern formed on the ceramic base;
electrode pattern parts included on the circuit pattern of the ceramic substrate and connected to electrodes of a semiconductor chip mounted on the ceramic substrate; and
a spacer bonded to the electrode pattern part of the ceramic substrate via a bonding layer,
wherein the spacer is made of metal or an alloy having electrical conductivity and thermal conductivity.

2. The ceramic substrate unit of claim 1, wherein the circuit pattern is made of one of Cu, Al, AlSiC, CuMo, CuW, Cu/CuMo/Cu, Cu/Mo/Cu, Cu/W/Cu alloys or a composite material thereof.

3. The ceramic substrate unit of claim 1, wherein the bonding layer is made of Ag sintering paste or made of an alloy material comprising AgCu or AgCuTi.

4. The ceramic substrate unit of claim 1, wherein a thickness of the bonding layer is in a range of 5 μm to 100 μm.

5. The ceramic substrate unit of claim 1, wherein the spacer is made of Cu, CuMo, or a CPC material in which Cu, CuMo, and Cu have been sequentially stacked.

6. The ceramic substrate unit of claim 1, wherein each spacer bonded to the electrode pattern part is connected to each electrode of the semiconductor chip.

7. The ceramic substrate unit of claim 1, wherein the spacers bonded to the electrode pattern parts are bonded to a source electrode, drain electrode, and gate electrode of the semiconductor chip, respectively, through soldering or sintering.

8. The ceramic substrate unit of claim 1, further comprising a plurality of spacers bonded to remaining parts except the electrode pattern parts in the circuit pattern via the bonding layer.

9. The ceramic substrate unit of claim 8, wherein the plurality of spacers bonded to the remaining parts except the electrode pattern parts in the circuit pattern via the bonding layer have a height greater than a sum of heights of the spacer bonded to the electrode pattern part and the semiconductor chip.

10. A method of manufacturing a ceramic substrate unit, comprising:
a step of preparing a ceramic substrate comprising a ceramic base, at least one circuit pattern formed on the ceramic base, and electrode pattern parts to be connected to electrodes of a semiconductor chip, respectively, on the circuit pattern;
a step of disposing a spacer on the electrode pattern parts of the ceramic substrate via a bonding layer;
a step of inserting and pre-heating the ceramic substrate in which the spacer has been disposed into a heating furnace; and
a step of main-bonding the spacer to the ceramic substrate by raising a temperature of the heating furnace after the pre-heating step.

11. The method of claim 10, wherein in the step of preparing the ceramic substrate, the circuit pattern is formed by brazing-bonding metal foil made of one of Cu, Al, AlSiC, CuMo, CuW, Cu/CuMo/Cu, Cu/Mo/Cu, Cu/W/Cu alloys or a composite material thereof to the ceramic base and then etching the metal foil.

12. The method of claim 10, wherein in the step of preparing the ceramic substrate, the electrode pattern parts are formed to comprise a source electrode pattern part, a drain electrode pattern part, and a gate electrode pattern part corresponding to a source electrode, drain electrode, and gate electrode of the semiconductor chip.

13. The method of claim 12, wherein in the step of disposing the spacer, the spacer made of a CuMo material or a CPC material in which Cu, CuMo, and Cu have been sequentially stacked is disposed in the source electrode pattern part and the drain electrode pattern part via a brazing bonding layer.

14. The method of claim 13, wherein the brazing bonding layer is made of an alloy material comprising AgCu or AgCuTi.

15. The method of claim 12, wherein in the step of disposing the spacer, the spacer made of a Cu material is disposed in the gate electrode pattern part via an Ag sintering bonding layer.

16. The method of claim 10, further comprising a step of disposing a plurality of spacers in remaining parts except the electrode pattern parts in the circuit pattern via the bonding layer,
wherein the plurality of spacers is made of a CuMo material or a CPC material in which Cu, CuMo, and Cu have been sequentially stacked.

17. The method of claim 10, wherein the step of inserting the ceramic substrate in which the spacer has been disposed into the heating furnace and pre-heating the heating furnace is performed at 700° C. to 900° C. for 10 minutes to 30 minutes.

18. The method of claim 10, wherein the step of main-bonding the spacer to the ceramic substrate by raising the temperature of the heating furnace after the pre-heating step is performed for 1 hour to 3 hours by making the heating furnace have a reduction atmosphere and raising the temperature of the heating furnace to 860° C. to 950° C.

19. The method of claim 10, wherein after the step of main-bonding the spacer to the ceramic substrate by raising the temperature of the heating furnace, a step of processing some spacers bonded to the ceramic substrate in a predetermined shape by etching the some spacers is performed.

20. The method of claim 10, wherein after the step of main-bonding the spacer to the ceramic substrate by raising the temperature of the heating furnace, a step of disposing the spacer made of a Cu material in at least one of the electrode pattern parts via an Ag sintering bonding layer and performing pre-heating and the main bonding is further performed.
